(19) United States
(12) Patent Application Publication
(10) Pub. No.: US 2026/0177914 A1
(43) Pub. Date: Jun. 25, 2026

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Hyun LEE, Suwon-si (KR); Joonhee HAN, Suwon-si (KR); Sumin JANG, Suwon-si (KR); Soobin LIM, Suwon-si (KR); Yunju CHAE, Suwon-si (KR); Kyungmog KIM, Suwon-si (KR)

(21) Appl. No.: 19/425,915

(22) Filed: Dec. 18, 2025

(30) Foreign Application Priority Data
Dec. 24, 2024 (KR) 10-2024-0196244

(51) Int. Cl. G03F 7/004; G03F 7/00; H10P 50/00; H10P 76/20

(52) U.S. Cl. CPC G03F 7/0045; G03F 7/0042; H10P 50/73; H10P 76/204; G03F 7/70033

(57) ABSTRACT

A semiconductor photoresist composition and a method of forming patterns using the semiconductor photoresist composition are provided. The semiconductor photoresist composition includes: an organometallic compound; a compound represented by Chemical Formula 1 or Chemical Formula 2; and a solvent.

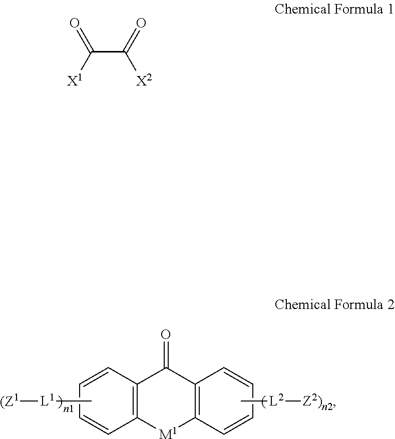

### CROSS-REFERENCE TO RELATED APPLICATION

The present application claims priority to and the benefit of Korean Patent Application No. 10-2024-0196244, filed on Dec. 24, 2024, in the Korean Intellectual Property Office, the entire content of which is incorporated herein by reference.

### BACKGROUND

### 1. Field

One or more embodiments of the present disclosure relate to a semiconductor photoresist composition and a method of forming patterns using the same.

### 2. Description of the Related Art

Extreme ultraviolet (EUV) lithography has emerged as an important technology for manufacturing next-generation semiconductor devices, such as advanced semiconductor chips (e.g., next generation semiconductor chips). EUV lithography utilizes EUV radiation with a wavelength of 13.5 nanometers (nm) as an exposure light source, enabling the formation of extremely fine patterns, for example, patterns having critical dimensions of 20 nm or less.

Achieving high-resolution patterning with EUV lithography requires the development of compatible photoresists capable of sub-16 nm resolution. However, chemically amplified (CA) photoresists currently face limitations in resolution, photospeed, and line edge roughness (LER), which hinder their performance in advanced lithographic processes.

In CA photoresists, acid-catalyzed reactions may cause image blurring, particularly at small feature sizes, a limitation also observed in electron beam lithography. Although CA photoresists are designed for high sensitivity, their typical elemental composition results in low absorbance at 13.5 nm, thereby reducing sensitivity under EUV exposure.

Additionally, CA photoresists often exhibit increased LER as photospeed decreases, due in part to the stochastic nature of acid diffusion and reaction. These limitations create the need for novel, high-performance photoresist materials suitable for EUV lithography.

In response, research has turned to inorganic photoresist compositions, which are primarily used for negative tone patterning. These compositions undergo chemical modification through non-chemically amplified mechanisms, providing resistance to developer solutions. Inorganic photoresists typically contain elements with higher EUV absorption than hydrocarbons, offering improved sensitivity, reduced stochastic effects, and lower LER.

Inorganic photoresists based on peroxopolyacids of tungsten, optionally mixed with elements, such as niobium, titanium, and/or tantalum, have been reported as radiation sensitive materials for patterning.

These materials have demonstrated efficacy in patterning large-pitch features using bilayer configurations and various radiation sources, including deep UV, X-ray, and electron beam. For example, cationic hafnium metal oxide sulfate (HfSOx) materials, when combined with a peroxo complexing agent, have enabled imaging of 15 nm half-pitch features via EUV projection exposure. While this system offers high performance and acceptable photospeed, it suffers from practical drawbacks: (i) the coating process involves corrosive sulfuric acid/hydrogen peroxide mixtures, leading to poor shelf-life stability; (ii) structural modifications for performance enhancement are difficult; and (iii) development requires highly concentrated tetramethylammonium hydroxide (TMAH) solutions (e.g., 25 wt %).

To address these issues and challenges, recent efforts have focused on tin-containing molecules with strong EUV absorption. Among these, organotin polymers have shown promise. Upon EUV exposure, alkyl ligands dissociate and form oxo bonds with adjacent chains, enabling negative tone patterning resistant to organic developers. Although these organotin polymers exhibit improved sensitivity, resolution, and LER, further enhancements are needed or desired to meet commercial performance requirements.

### SUMMARY

One or more aspects of embodiments of the present disclosure are directed toward a semiconductor photoresist composition that has excellent or suitable sensitivity and improved storage stability and coatability.

One or more aspects of embodiments of the present disclosure are directed toward a method of forming patterns using the semiconductor photoresist composition.

Additional aspects will be set forth in part in the description which follows and, in part, will be apparent from the description, or may be learned by practice of the presented embodiments of the disclosure.

According to one or more embodiments of the present disclosure, a semiconductor photoresist composition includes: an organometallic compound; a compound represented by Chemical Formula 1 or Chemical Formula 2; and a solvent:

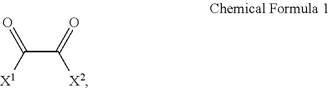

wherein, in Chemical Formula 1,
X¹ and X² may each independently be a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C20 cycloalkyl group, a substituted or unsubstituted C3 to C20 cycloalkenyl group, a substituted or unsubstituted C2 to C20 heterocycloalkyl group, a substituted or unsubstituted C3 to C20 heteroaryl group, or a substituted or unsubstituted C6 to C20 aryl group, and/or X¹ and X² are linked to each other to form a single or a plurality of rings;

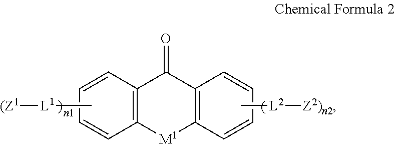

wherein, in Chemical Formula 2,
M¹ may be —C(═O)—, —O—, —S—, —N(-L^{x}-R^{x})— (wherein, L^{x} may be a single bond or a substituted or unsubstituted C1 to C5 alkylene group, and R^{x} may be hydrogen, a carboxyl group, or a substituted or unsubstituted C1 to C5 alkyl group), or a combination thereof,
L¹ and L² may each independently be a single bond or a substituted or unsubstituted C1 to C5 alkylene group,
Z¹ and Z² may each independently be a hydroxyl group, a halogen, a cyano group, a cyano-containing group, an amino group, an ammonium group, an amide group, a nitro group, a carboxyl group, an ester group, a sulfone group, a sulfonate group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, or a combination thereof, and
n1 and n2 may each independently be one of integers from 0 to 4.

The semiconductor photoresist composition according to one or more embodiments has excellent or suitable sensitivity, storage stability, and coatability, and thus enables precise control of small-sized patterns and implementation of excellent or suitable resolution.

For example, one or more embodiments of the present disclosure provide a semiconductor photoresist composition and associated pattern-forming methods that collectively address critical limitations of comparable chemically amplified photoresists in EUV lithography. By incorporating an organometallic compound—such as an organotin species—together with a compound represented by Chemical Formula 1 or Chemical Formula 2 and a suitable solvent, the disclosed composition achieves enhanced EUV absorption, improved sensitivity, and superior storage stability. The cyclic moieties and carbonyl functionalities of the embodied compounds promote controlled crosslinking and coordination with metal centers, thereby reducing line edge roughness and enabling formation of fine patterns with critical dimensions in the single-digit nanometer range. These synergistic features, supported by the detailed embodiments herein, allow precise pattern fidelity while maintaining coatability and process compatibility.

### BRIEF DESCRIPTION OF THE DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments of the disclosure will be more apparent from the following description taken in conjunction with the accompanying drawings, in which:

FIGS. 1A-1E are cross-sectional views illustrating a method of forming patterns using a semiconductor photoresist composition according to one or more embodiments of the present disclosure.

### DETAILED DESCRIPTION

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the teachings and scope of the present disclosure.

Hereinafter, referring to the drawings, one or more embodiments of the present disclosure will be described in more detail. In the following description of the present disclosure, the well-established functions or constructions will not be described in order to make the present disclosure concise.

To clearly illustrate the present disclosure, certain unessential description and relationships are omitted, and throughout the disclosure, the same or similar configuration elements are designated by the same reference numerals. Also, because the size and thickness of each configuration shown in the drawing are illustratively shown for better understanding and ease of description, the present disclosure is not necessarily limited thereto.

In the drawings, the thickness of layers, films, panels, regions, and/or the like, may be enlarged or reduced for clarity. In the drawings, the thickness of a part of layers or regions, and/or the like, may be exaggerated or reduced for convenience of explanation. It will be understood that if (e.g., when) an element such as a layer, film, region, or substrate is referred to as being “on” another element, it may be directly on the other element, or one or more intervening elements may also be present therebetween. In contrast, when an element is referred to as being “directly on” another element, there are no intervening elements present therebetween.

As used herein, “substituted” refers to replacement of a hydrogen atom by deuterium, a halogen, a hydroxyl group, a carboxyl group, a thiol group, a cyano group, a nitro group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen by another substituent and remaining of the hydrogen.

As used herein, if (e.g., when) a definition is not otherwise provided, the term “alkyl group” refers to a linear or branched aliphatic hydrocarbon group. The alkyl group may be a “saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, the term “cycloalkyl group” refers to a monovalent cyclic aliphatic hydrocarbon group.

The cycloalkyl group may be a C3 to C8 cycloalkyl group, for example, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but embodiments of the present disclosure are not limited thereto.

As used herein, the term “aryl group” refers to a substituent in which all atoms in the cyclic substituent have a p-orbital and these p-orbitals are conjugated and may include a monocyclic functional group or a fused ring polycyclic functional group (i.e., rings sharing adjacent pairs of carbon atoms).

As used herein, the term “heteroaryl group” may refer to an aryl group including at least one heteroatom selected from among N, O, S, P, and Si. Two or more heteroaryl groups may be linked by a sigma bond directly, or if (e.g., when) the heteroaryl group includes two or more rings, the two or more rings may be fused. When the heteroaryl group is a fused ring, one or more rings thereof may include one to three heteroatoms.

As used herein, the term “alkenyl group” may refer to a linear or branched aliphatic hydrocarbon group including at least one double bond as an aliphatic unsaturated alkenyl group.

As used herein, the term “alkynyl group” may refer to a linear or branched aliphatic hydrocarbon group including at least one triple bond as an aliphatic unsaturated alkynyl group.

Hereinafter, a semiconductor photoresist composition according to one or more embodiments will be described.

A semiconductor photoresist composition according to one or more embodiments may include: an organometallic compound; a compound represented by Chemical Formula 1 or Chemical Formula 2; and a solvent:

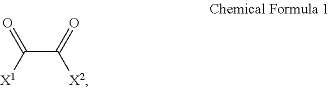

wherein, in Chemical Formula 1,
X¹ and X² may each independently be a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C20 cycloalkyl group, a substituted or unsubstituted C3 to C20 cycloalkenyl group, a substituted or unsubstituted C2 to C20 heterocycloalkyl group, a substituted or unsubstituted C3 to C20 heteroaryl group, or a substituted or unsubstituted C6 to C20 aryl group, and/or X¹ and X² are linked to each other to form a single or a plurality of rings;

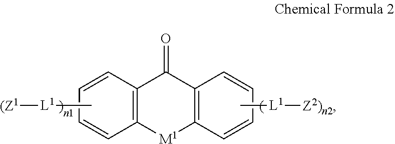

wherein, in Chemical Formula 2,
M¹ may be —C(═O)—, —O—, —S—, —N(-L^{x}-R^{x})— (wherein, L^{x} may be a single bond or a substituted or unsubstituted C1 to C5 alkylene group, and R^{x} may be hydrogen, a carboxyl group, or a substituted or unsubstituted C1 to C5 alkyl group), or a combination thereof,
L¹ and L² may each independently be a single bond or a substituted or unsubstituted C1 to C5 alkylene group,
Z¹ and Z² may each independently be a hydroxyl group, a halogen, a cyano group, a cyano-containing group, an amino group, an ammonium group, an amide group, a nitro group, a carboxyl group, an ester group, a sulfone group, a sulfonate group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, or a combination thereof, and
n1 and n2 may each independently be one of integers from 0 to 4.

The compound represented by Chemical Formula 1 may act as a chelating ligand that weakly links tin (Sn) and tin (Sn) of the organometallic compounds in the semiconductor photoresist composition by linking two carbonyl groups (—C═O—) adjacent to each other. In addition, the compound represented by Chemical Formula 2 may also act as a bridging ligand between tin (Sn) and tin (Sn) of the organometallic compounds in the composition, as it contains a carbonyl group (—C═O—). Therefore, the semiconductor photoresist composition according to one or more embodiments including a compound represented by Chemical Formula 1 or Chemical Formula 2 has improved coatability and sensitivity, and also improves line etch roughness (LWR), thereby enabling excellent or suitable pattern formation.

Because the compounds represented by Chemical Formula 1 and the compounds represented by Chemical Formula 2 contain heteroatoms having relatively high electronegativity, they may become ligands that coordinate with metals or metal cations. Additionally, the compounds may be cyclic, and the cyclic compounds may have relatively restricted molecular shapes, thus having lower entropy compared to linear compounds, and may have higher binding affinity with metals.

When the compound is a cyclic compound and a heteroatom is contained in the ring within the compound, the compound may act as a competitive inhibitor for the reaction between the solvent and the metal cation within the composition, thereby further improving the storage stability of the composition. In addition, the compound may promote the reaction of the organometallic compound in the exposed region, thereby reducing the amount of composition desired or required for pattern formation, while reducing a degree of crosslinking of the organometallic compounds in the unexposed region, thereby stably forming a pattern during the exposure process.

In Chemical Formula 1, in one or more embodiments, X¹ and X² may each independently be a substituted or unsubstituted C1 to C20 alkoxy group, a substituted or unsubstituted C1 to C20 alkyl group, a substituted or unsubstituted C2 to C20 alkenyl group, a substituted or unsubstituted C2 to C20 alkynyl group, a substituted or unsubstituted C3 to C20 cycloalkyl group, or a substituted or unsubstituted C6 to C20 aryl group, and/or X¹ and X² may be linked to each other to form a single or a plurality of rings; in one or more embodiments, X¹ and X² may be a substituted or unsubstituted C1 to C20 alkoxy group, a substituted or unsubstituted C1 to C20 alkyl group, a substituted or unsubstituted C3 to C10 cycloalkyl group, a substituted or unsubstituted C6 to C20 aryl group, or a combination thereof, and/or X¹ and X² may be linked to each other to form a single or a plurality of rings.

In Chemical Formula 1, in one or more embodiments, X¹ and X² may be independently a substituted or unsubstituted C1 to C20 alkoxy group, a substituted or unsubstituted C6 to C20 aryl group, or a combination thereof, and at least one selected from among X¹ and X² may be a substituted or unsubstituted C6 to C20 aryl group. The substituted or unsubstituted C1 to C20 alkoxy group may be a substituted or unsubstituted methoxy group, or a substituted or unsubstituted ethoxy group, and the substituted or unsubstituted C6 to C20 aryl group may be a substituted or unsubstituted phenyl group or a substituted or unsubstituted naphthyl group.

In Chemical Formula 1, in one or more embodiments, X¹ and X² may each independently be a substituted or unsubstituted C1 to C20 alkyl group, a substituted or unsubstituted C3 to C10 cycloalkyl group, a substituted or unsubstituted C6 to C20 aryl group, or a combination thereof, and/or X¹ and X² may be linked to each other to form a single or a plurality of rings. For example, in one or more embodiments, X¹ and X² may each be a phenyl group, and any carbon atom of each phenyl group may be linked to form a ring. In one or more embodiments, one selected from among X¹ and X² may be a substituted or unsubstituted cycloalkyl group and the other may be a substituted or unsubstituted alkyl group, and one of the carbons in the cycloalkyl group and the alkyl group may be linked to form a plurality of rings.

In one or more embodiments, the compound represented by Chemical Formula 1 may include, for example, one or more of the compounds selected from among Group 1:

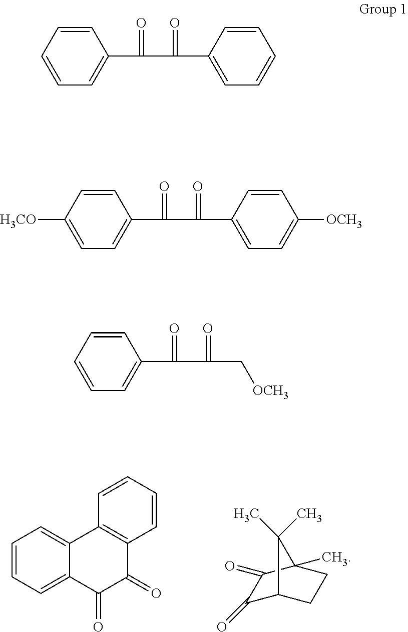 [SMILES: O=C(C(=O)c1ccccc1)c1ccccc1 ; COc1ccc(C(=O)C(=O)c2ccc(OC)cc2)cc1 ; COCC(=O)C(=O)c1ccccc1 ; O=C1C(=O)c2ccccc2-c2ccccc21 ; CC12CCC(C(=O)C1=O)C2(C)C]

In Chemical Formula 2, in one or more embodiments, M¹ may be —C(═O)—, —O—, —S—, —N(-L^{x}-R^{x})— (wherein, L^{x} may be a single bond or a substituted or unsubstituted C1 to C5 alkylene group, and R^{x} may be hydrogen, a carboxyl group, or a substituted or unsubstituted C1 to C5 alkyl group), or a combination thereof; in one or more embodiments, M¹ may be —C(═O)—, —O—, —S—, —N(-L^{x}-R^{x})— (wherein, L^{x} may be a single bond or a methylene group, and R^{x} may be hydrogen, a carboxyl group, or a methyl group), or a combination thereof.

In Chemical Formula 2, in one or more embodiments, L¹ and L² may each independently be a single bond or a substituted or unsubstituted C1 to C5 alkylene group; in one or more embodiments, L¹ and L² may each independently be a single bond or a methylene group.

In Chemical Formula 2, in one or more embodiments, Z¹ and Z² may each independently be a hydroxyl group, a halogen, a carboxyl group, an ester group, a sulfone group, a sulfonate group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, or a combination thereof; in one or more embodiments, Z¹ and Z² may each independently be a hydroxyl group, a halogen, a carboxyl group, an ester group, a sulfone group, a sulfonate group, a substituted or unsubstituted C1 to C20 alkoxy group, a substituted or unsubstituted C1 to C20 alkyl group, or a substituted or unsubstituted C2 to C20 alkenyl group; in one or more embodiments, Z¹ and Z² may each independently be a halogen, a carboxyl group, a sulfonate group, a substituted or unsubstituted C1 to C20 alkoxy group, or a substituted or unsubstituted C1 to C20 alkyl group.

In Chemical Formula 2, in one or more embodiments, n1 and n2 may be one of the integers from 0 to 4, for example, one of the integers from 0 to 3, one of the integers from 0 to 2, for example, 0 or 1.

In one or more embodiments, the compound represented by Chemical Formula 2 may include at least one selected from among compounds selected from among Group 2:

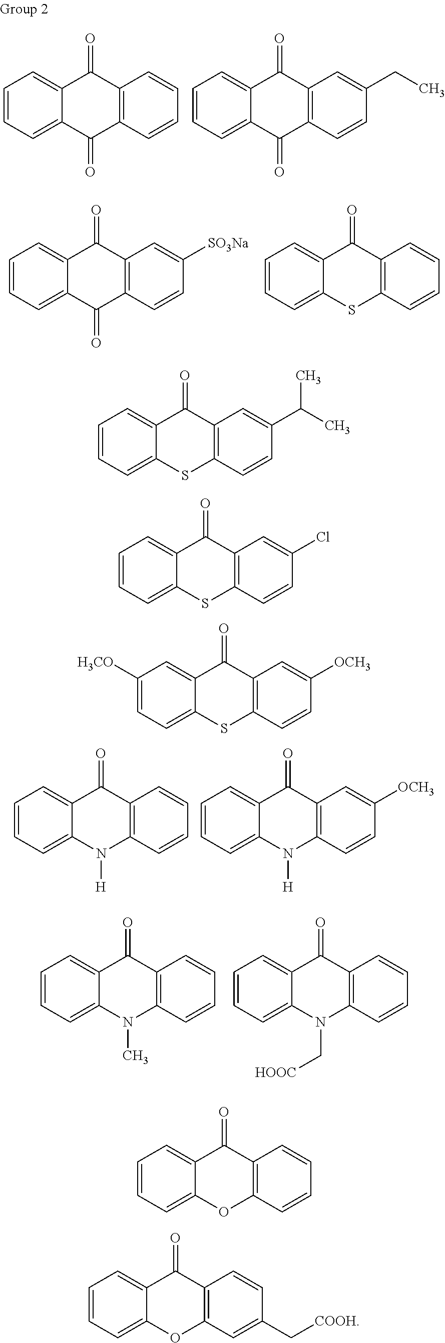

The compound represented by Chemical Formula 1 or Chemical Formula 2 may be included in an amount of about 0.01 wt % to about 5 wt %, about 0.02 wt % to about 5 wt %, about 0.03 wt % to about 5 wt %, or about 0.05 wt % to about 5 wt %, based on a total weigh of 100 wt % of the semiconductor photoresist composition. When the compound represented by Chemical Formula 1 or Chemical Formula 2 is included within the above ranges, storage stability and sensitivity of the composition may be further improved.

The organometallic compound may be included in an amount of about 0.5 wt % to about 30 wt % based on a total weight of 100 wt % of the semiconductor photoresist composition. In the semiconductor photoresist composition according to one or more embodiments, the organometallic compound may be included in an amount of about 0.5 wt % to about 30 wt %, for example, about 1 wt % to about 30 wt %, for example about 1 wt % to about 25 wt %, for example, about 1 wt % to about 20 wt %, for example, about 1 wt % to about 15 wt %, for example, about 1 wt % to about 10 wt %, for example, about 1 wt % to about 5 wt %, based on the total weight of 100 wt % of the semiconductor photoresist composition.

The semiconductor photoresist composition according to one or more embodiments may improve the sensitivity of the photoresist by including the organometallic compound within the above amount range.

In one or more embodiments, the organometallic compound may be an organotin compound including at least one of an organic oxy group or an organic carbonyloxy group.

In one or more embodiments, the organometallic compound may be represented by Chemical Formula 3:

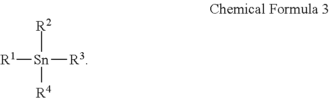

In Chemical Formula 3,
R¹ may be selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R² to R⁴ may each independently be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an acyloxy or a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido or dialkylamido group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)R^{j}, wherein R^{h}, Rⁱ, and R^{j} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio or arylthio group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), or a thiocarboxyl group (—S(CO)R^{l}, wherein R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and
at least one selected from among R² to R⁴ may be selected from among an alkoxy group and an aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an acyloxy group and a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylamido group and an dialkylamido group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidato group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an amidinato group (—NR^{h}C(NRⁱ)R^{j}, wherein R^{h}, Rⁱ, and R^{j} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), an alkylthio group and an arylthio group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and a thiocarboxyl group (—S(CO)R^{l}, wherein R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

In one or more embodiments, at least one selected from among R² to R⁴ may be selected from among an alkoxy group and an aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof), and an acyloxy group and a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

In one or more embodiments, because the organometallic compound represented by the Chemical Formula 3 includes —OR^{b} and/or —OC(═O)R^{c} as ligand(s), a pattern formed using a semiconductor photoresist composition including the organometallic compound may exhibit excellent or suitable limit resolution.

Additionally, the ligand(s) of —OR^{b} and/or —OC(═O)R^{c} may determine the solubility of the organometallic compound represented by Chemical Formula 3 in a solvent.

In one or more embodiments, R¹ may be selected from among a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, and a substituted or unsubstituted C7 to C20 arylalkyl group,
R^{b} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

In one or more embodiments, R¹ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof,
R^{b} may be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof, and
R^{c} may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

In one or more embodiments, the organometallic compound may be represented by Chemical Formula 4 or Chemical Formula 5:

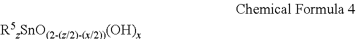

wherein, in Chemical Formula 4,
R⁵ may be a C1 to C31 hydrocarbyl group, 0<z≤2, and 0<(z+x)≤4;

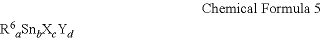

wherein, in Chemical Formula 5,
R⁶ may be a substituted or unsubstituted C1 to C20 alkyl group, a substituted or unsubstituted C3 to C20 cycloalkyl group, a substituted or unsubstituted C2 to C20 aliphatic unsaturated organic group including one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X may be sulfur (S), selenium (Se), or tellurium (Te),
Y may be —OR^{m} or —OC(═O)Rⁿ,
wherein R^{m} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
Rⁿ may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d may each independently be an integer of 1 to 20.

The semiconductor resist composition according to one or more embodiments may further include a resin in addition to the aforementioned organometallic compound, compound represented by Chemical Formula 1 or Chemical Formula 2, and solvent.

The resin may be a phenol-based resin including at least one aromatic moiety listed in Group 3. For example, the resin may be a phenol-based resin including at least one aromatic moiety selected from the aromatic moieties listed in Group 3.

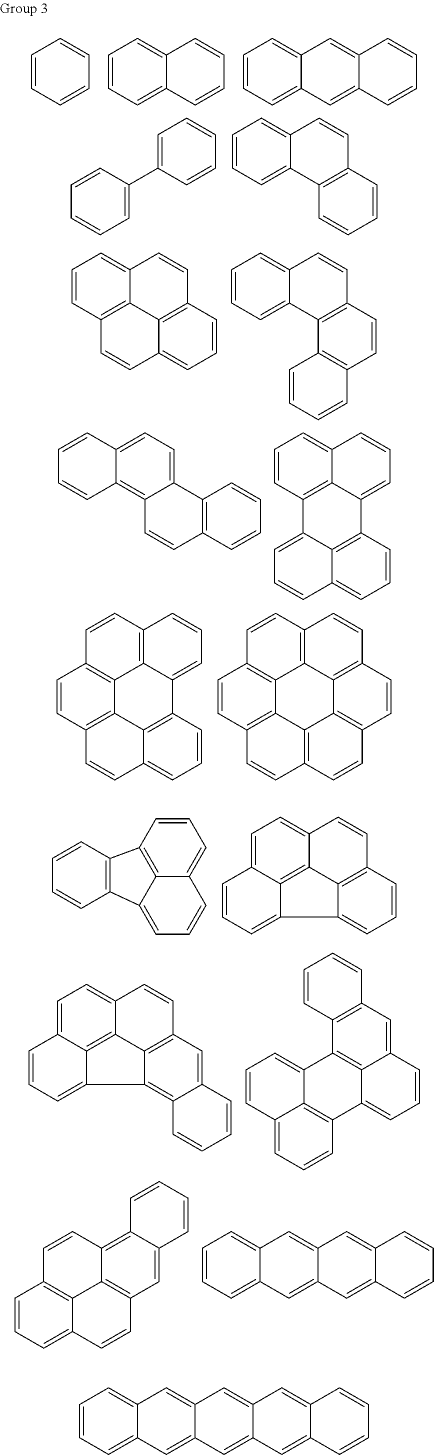

The resin may have a weight average molecular weight of about 500 g/mol to about 20,000 g/mol.

In one or more embodiments, the semiconductor photoresist composition may be composed of the aforementioned organometallic compound, compound represented by Chemical Formula 1 or Chemical Formula 2, solvent, and resin.

The solvent included in the semiconductor photoresist composition according to one or more embodiments may be an organic solvent, for example, may be selected from aromatic compounds (e.g., xylene and/or toluene), alcohols (e.g., 4-methyl-2-pentanol, 4-methyl-2-propanol, 1-butanol, methanol, isopropyl alcohol, and/or 1-propanol), ethers (e.g., anisole and/or tetrahydrofuran), esters (n-butyl acetate, propylene glycol monomethyl ether acetate, ethyl acetate, and/or ethyl lactate), ketones (e.g., methyl ethyl ketone and/or 2-heptanone), and/or a mixture thereof, but embodiments of the present disclosure are not limited thereto.

The semiconductor photoresist composition according to one or more embodiments may further include an additive, if necessary. Non-limiting examples of the additive may include a surfactant, a crosslinking agent, a leveling agent, organic acid, a quencher, or a combination thereof.

The surfactant may include, for example, an alkyl benzene sulfonate salt, an alkyl pyridinium salt, polyethylene glycol, a quaternary ammonium salt, or a combination thereof, but embodiments of the present disclosure are not limited thereto.

The crosslinking agent may be, for example, a melamine-based crosslinking agent, a substituted urea-based crosslinking agent, an acrylic crosslinking agent, an epoxy-based crosslinking agent, or a polymer-based crosslinking agent, but embodiments of the present disclosure are not limited thereto. In one or more embodiments, it may be a crosslinking agent having at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be used to improve coating flatness during printing and may be a commercially available suitable leveling agent.

The organic acid may be p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but embodiments of the present disclosure are not limited thereto.

The quencher may be diphenyl (p-tolyl) amine, methyl diphenyl amine, triphenyl amine, phenylenediamine, naphthylamine, diaminonaphthalene, or a combination thereof.

An amount of each of the additives included in the semiconductor photoresist composition may be controlled or selected depending on desired or suitable properties.

In one or more embodiments, the semiconductor photoresist composition may further include a silane coupling agent as an adherence enhancer in order to improve a close-contacting force with a substrate (e.g., in order to improve adherence of the semiconductor photoresist composition to the substrate). The silane coupling agent may include, for example, a silane compound including a carbon-carbon unsaturated bond such as vinyltrimethoxysilane, vinyl triethoxysilane, vinyl trichlorosilane, vinyl tris(β-methoxyethoxy) silane; 3-methacryloxypropyltrimethoxysilane, 3-acryloxypropyltrimethoxysilane, p-styryl trimethoxysilane, 3-methacryloxypropylmethyldimethoxysilane, or 3-methacryloxypropylmethyl diethoxysilane; trimethoxy[3-(phenylamino)propyl]silane; and/or the like, but embodiments of the present disclosure are not limited thereto.

The semiconductor photoresist composition may be formed into a pattern having a high aspect ratio without a collapse. Accordingly, in order to form a fine pattern having a width (e.g., line width) of, for example, about 5 nm to about 100 nm (e.g., to form the fine pattern having a critical dimension (CD) of about 5 nm to about 100 nm), for example, about 5 nm to about 80 nm, for example, about 5 nm to about 70 nm, for example, about 5 nm to about 50 nm, for example, about 5 nm to about 40 nm, for example, about 5 nm to about 30 nm, or for example, about 5 nm to about 20 nm, the semiconductor photoresist composition may be used for a photoresist process using light in a wavelength in a range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to one or more embodiments may be used to realize extreme ultraviolet lithography using an EUV light source of a wavelength of about 13.5 nm.

According to one or more embodiments, a method of forming patterns using the aforementioned semiconductor photoresist composition is provided. For example, the manufactured pattern may be a photoresist pattern.

The method of forming patterns according to one or more embodiments includes forming an etching-objective layer (e.g., etching-target layer) on a substrate, applying the semiconductor photoresist composition to the etching-objective layer to form a photoresist film, patterning the photoresist film to form a photoresist pattern, and etching the etching-objective layer using the photoresist pattern as an etching mask.

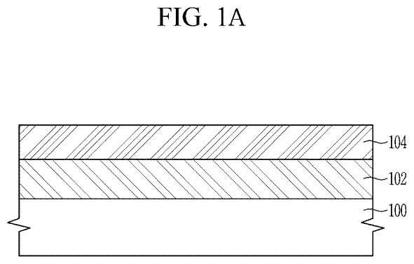

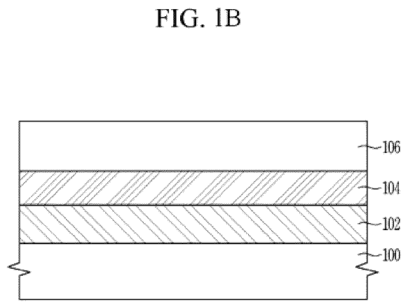

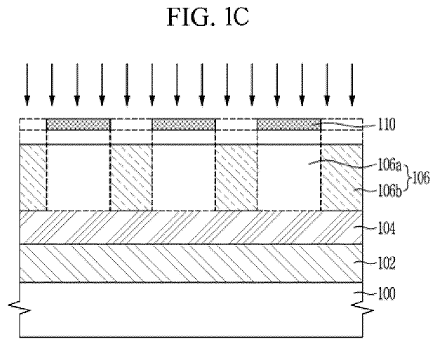

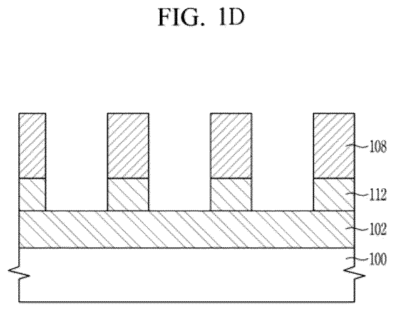

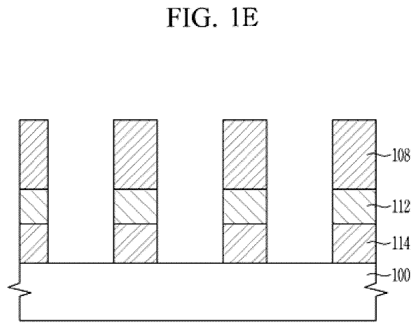

Hereinafter, a method of forming patterns using the aforementioned semiconductor photoresist composition will be described in more detail referring to FIGS. 1A to 1E. FIGS. 1A to 1E are cross-sectional views for explaining a method of forming patterns using a semiconductor photoresist composition according to one or more embodiments.

Referring to FIG. 1A, an object for etching (e.g., etching-objective layer or etching-target layer)) is prepared. The object for etching may be a thin film 102 formed on a semiconductor substrate 100. Hereinafter, the object for etching is limited to the thin film 102. A surface of the thin film 102 is washed to remove impurities and/or the like remaining thereon. The thin film 102 may be, for example, a silicon nitride layer, a polysilicon layer, or a silicon oxide layer.

Subsequently, a resist underlayer composition for forming a resist underlayer 104 is spin-coated on the surface of the washed thin film 102. However, the embodiments of the present disclosure are not limited thereto, and various suitable coating methods, for example, a spray coating, a dip coating, a knife edge coating, a printing method (for example, an inkjet printing and/or a screen printing), and/or the like may be used.

In one or more embodiments, the coating process of the resist underlayer may not be provided, but hereinafter, a process including a coating of the resist underlayer is described.

Then, the coated resist underlayer composition is dried and baked to form a resist underlayer 104 on the thin film 102. In one or more embodiments, the baking may be performed at about 100° C. to about 500° C., for example, about 100° C. to about 300° C.

The resist underlayer 104 is formed between the substrate 100 and a photoresist film 106 and thus may prevent or reduce non-uniformity of pattern formability of a photoresist line width if (e.g., when) a ray reflected from on the interface between the substrate 100 and the photoresist film 106 or a hardmask between layers is scattered into an unintended photoresist region.

Referring to FIG. 1B, the photoresist film 106 is formed by coating the semiconductor photoresist composition on the resist underlayer 104. The photoresist film 106 is obtained by coating the aforementioned semiconductor photoresist composition on the thin film 102 formed on the substrate 100 and then, curing it through a heat treatment.

In one or more embodiments, the formation of a pattern by using the semiconductor photoresist composition may include coating the semiconductor resist composition on the substrate 100 having the thin film 102 through spin coating, slit coating, inkjet printing, and/or the like and then, drying it to form the photoresist film 106.

The semiconductor photoresist composition has already been illustrated in more detail and will not be illustrated again.

Subsequently, the substrate 100 having the photoresist film 106 is subjected to a first baking process. The first baking process may be performed at about 80° C. to about 120° C.

Referring to FIG. 1C, the photoresist film 106 may be selectively exposed using a patterned mask 110.

For example, the exposure may use an activation radiation with light having a high energy wavelength light such as EUV (extreme ultraviolet; a wavelength of about 13.5 nm), an E-Beam (an electron beam), and/or the like as well as light such as an i-line (a wavelength of about 365 nm), a KrF excimer laser (a wavelength of about 248 nm), an ArF excimer laser (a wavelength of about 193 nm), and/or the like.

In one or more embodiments, light or exposure beam for the exposure may be light having a wavelength in a range of about 5 nm to about 150 nm and/or a high energy wavelength, for example, EUV (extreme ultraviolet; a wavelength of 13.5 nm), and/or may be an E-Beam (an electron beam), and/or the like.

The exposed region 106b of the photoresist film 106 has a different solubility from the unexposed region 106a of the photoresist film 106 by forming a polymer by a crosslinking reaction such as condensation between organometallic compounds.

Subsequently, the substrate 100 is subjected to a second baking process. In one or more embodiments, the second baking process may be performed at a temperature of about 90° C. to about 200° C. The exposed region 106b of the photoresist film 106 becomes indissoluble regarding a developer due to the second baking process.

In FIG. 1D, the unexposed region 106a of the photoresist film is dissolved and removed using the developer to form a photoresist pattern 108. For example, the unexposed region 106a of the photoresist film is dissolved and removed by using an organic solvent such as 2-heptanone and/or the like to complete the photoresist pattern 108 corresponding to a negative tone image.

As described above, the developer used in the method of forming patterns according to one or more embodiments may be an organic solvent. The organic solvent used in the method of forming patterns according to one or more embodiments may be, for example, a ketone such as methylethylketone, acetone, cyclohexanone, 2-heptanone, and/or the like, an alcohol such as 4-methyl-2-propanol, 1-butanol, isopropanol, 1-propanol, methanol, and/or the like, an ester such as propylene glycol monomethyl ether acetate, ethyl acetate, ethyl lactate, n-butyl acetate, butyrolactone, and/or the like, an aromatic compound such as benzene, xylene, toluene, and/or the like, or a combination thereof.

However, the photoresist pattern according to one or more embodiments is not necessarily limited to the negative tone image but may be formed to have a positive tone image. In this regard, a developer used for forming the positive tone image may be a quaternary ammonium hydroxide composition including, such as tetraethylammonium hydroxide, tetrapropylammonium hydroxide, tetrabutylammonium hydroxide, or a combination thereof.

As described above, exposure to light having a high energy such as EUV (extreme ultraViolet; a wavelength of 13.5 nm), to an E-Beam (an electron beam), and/or the like, and/or to light such as i-line (wavelength of about 365 nm), KrF excimer laser (wavelength of about 248 nm), ArF excimer laser (wavelength of about 193 nm), and/or the like may provide a photoresist pattern 108 having a width of a thickness of about 5 nm to about 100 nm. For example, in one or more embodiments, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In one or more embodiments, the photoresist pattern 108 may have a pitch (center-to-center distance between adjacent features in the pattern) having a half-pitch of less than or equal to about 50 nm, for example less than or equal to about 40 nm, for example less than or equal to about 30 nm, for example less than or equal to about 20 nm, or for example less than or equal to about 15 nm, and a line width roughness of less than or equal to about 10 nm, less than or equal to about 5 nm, less than or equal to about 3 nm, or less than or equal to about 2 nm.

Subsequently, the photoresist pattern 108 is used as an etching mask to etch the resist underlayer 104. Through this etching process, an organic film pattern 112 is formed. The organic film pattern 112 may also have a width corresponding to that of the photoresist pattern 108.

Referring to FIG. 1E, the exposed thin film 102 is etched by applying the photoresist pattern 108 as an etching mask. As a result, the thin film is formed as a thin film pattern 114.

The etching of the thin film 102 may be performed by dry etching using, for example, an etching gas, and the etching gas may be, for example, CHF₃, CF₄, Cl₂, BCl₃, or a mixed gas thereof.

In the exposure process, the thin film pattern 114 formed by using the photoresist pattern 108 formed through the exposure process performed by using an EUV light source may have a width corresponding to that of the photoresist pattern 108. For example, the thin film pattern 114 may have a width (e.g., line width) of about 5 nm to about 100 nm which is equal to that of the photoresist pattern 108. For example, in one or more embodiments, the thin film pattern 114 formed by using the photoresist pattern 108 formed through the exposure process performed by using an EUV light source may have a width (e.g., line width) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, for example, a width (e.g., line width) of less than or equal to about 20 nm, like that of the photoresist pattern 108.

Hereinafter, the present disclosure will be described in more detail through examples of the preparation of the aforementioned semiconductor photoresist composition. However, the present disclosure is technically not restricted by the following examples.

### Synthesis of Organometallic Compounds

### Synthesis Example 1

40.7 g of t-butylSnPh₃ and 300 g of propionic acid were added to a 250 mL two-necked round-bottom flask and heated under reflux for 24 hours. Unreacted propionic acid was removed under reduced pressure to obtain a compound represented by Chemical Formula 6.

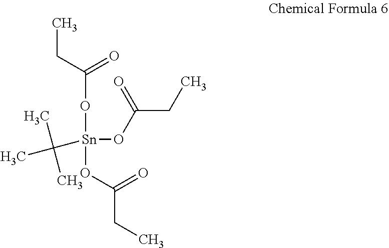 [SMILES: CCC(=O)[O][Sn]([O]C(=O)CC)([O]C(=O)CC)[C](C)(C)C]

### Synthesis Example 2

30 mL of anhydrous pentane was added to 10 g of t-AmylSnCl₃, the temperature was maintained at 0° C., and then 7.4 g of diethylamine and 6.1 g of ethanol were added thereto, and stirred at room temperature for 1 hour. When the reaction was completed, the resultant was filtered, concentrated, and vacuum-dried to obtain a compound represented by Chemical Formula 7.

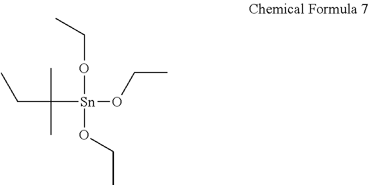

### Synthesis Example 3

10 g of dibutyltin dichloride was dissolved 30 mL of ether, 70 mL of a 1 M sodium hydroxide (NaOH) aqueous solution was added thereto and then, stirred for hour. After the stirring, a solid produced therein was filtered, three times washed with 25 mL of deionized water, and dried at 100° C. under a reduced pressure to obtain an organometallic compound represented by Chemical Formula 8 and having a weight average molecular weight of 1,500 g/mol.

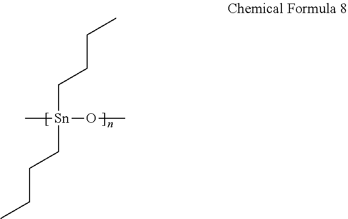

### Preparation of Semiconductor Photoresist Compositions

### Examples and Comparative Examples

The organometallic compounds represented by Chemical Formulas 6 to 8 according to Synthesis Examples 1 to 3 were respectively dissolved with one of compounds represented by Chemical Formulas 1-1 to 1-3, Chemical Formulas 2-1 to 2-4, and Chemical Formulas 9 and 10 in propylene glycol methyl ether acetate (PGMEA) at a respective concentration shown in Table 1 and then, filtered with a 0.1 μm PTFE (polytetrafluoroethylene) syringe filter, preparing respective semiconductor photoresist compositions according to examples and comparative examples. Each of the compositions was coated to be 240 angstroms (Å) thick on a silicon wafer and processed through PAB (post-apply bake), exposure, PEB (post-exposure bake), and development, forming a corresponding patterned film.

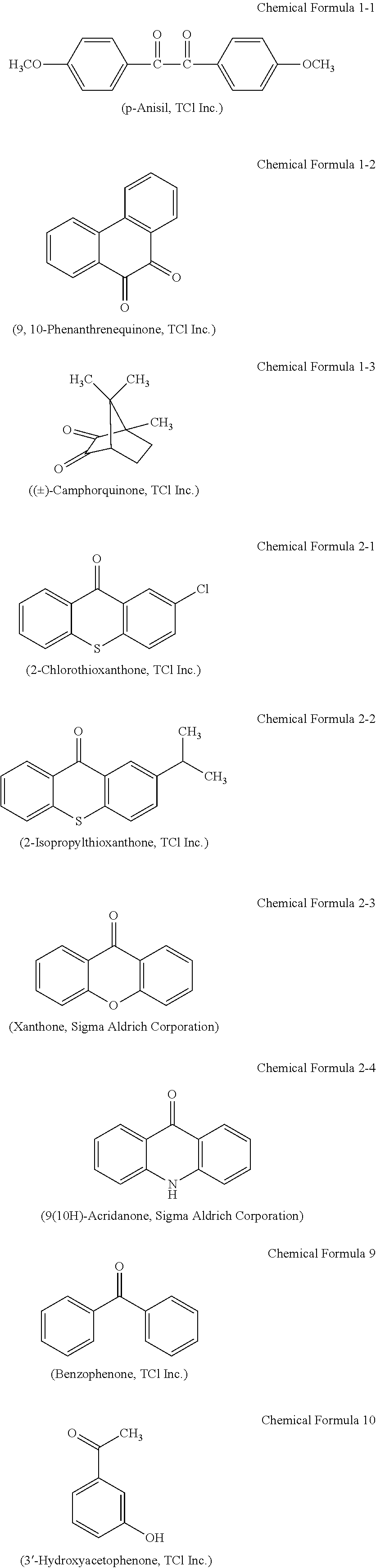

TABLE 1

| | Organometallic compound | Compound |
|---|---|---|
| | (wt %) | (wt %) |
| Example 1 | Chemical Formula 6 | Chemical Formula 1-1 |
| | (3.0) | (0.1) |
| Example 2 | Chemical Formula 6 | Chemical Formula 1-2 |
| | (3.0) | (0.1) |
| Example 3 | Chemical Formula 6 | Chemical Formula 1-2 |
| | (3.0) | (0.2) |
| Example 4 | Chemical Formula 6 | Chemical Formula 1-2 |
| | (3.0) | (0.3) |
| Example 5 | Chemical Formula 6 | Chemical Formula 1-3 |
| | (3.0) | (0.1) |
| Example 6 | Chemical Formula 7 | Chemical Formula 1-1 |
| | (3.0) | (0.1) |
| Example 7 | Chemical Formula 7 | Chemical Formula 1-2 |
| | (3.0) | (0.1) |
| Example 8 | Chemical Formula 7 | Chemical Formula 1-3 |
| | (3.0) | (0.1) |
| Example 9 | Chemical Formula 6 | Chemical Formula 2-1 |
| | (3.0) | (0.1) |
| Example 10 | Chemical Formula 6 | Chemical Formula 2-2 |
| | (3.0) | (0.1) |
| Example 11 | Chemical Formula 6 | Chemical Formula 2-3 |
| | (3.0) | (0.1) |
| Example 12 | Chemical Formula 6 | Chemical Formula 2-3 |
| | (3.0) | (0.2) |
| Example 13 | Chemical Formula 6 | Chemical Formula 2-3 |
| | (3.0) | (0.3) |
| Example 14 | Chemical Formula 6 | Chemical Formula 2-4 |
| | (3.0) | (0.1) |
| Example 15 | Chemical Formula 7 | Chemical Formula 2-1 |
| | (3.0) | (0.1) |
| Example 16 | Chemical Formula 7 | Chemical Formula 2-2 |
| | (3.0) | (0.1) |
| Example 17 | Chemical Formula 7 | Chemical Formula 2-3 |
| | (3.0) | (0.1) |
| Example 18 | Chemical Formula 7 | Chemical Formula 2-4 |
| | (3.0) | (0.1) |
| Example 19 | Chemical Formula 6 | Chemical Formula 1-2 |
| | (2.5) | (0.1) |
| Example 20 | Chemical Formula 6 | Chemical Formula 1-2 |
| | (3.5) | (0.1) |
| Example 21 | Chemical Formula 6 | Chemical Formula 2-3 |
| | (3.5) | (0.1) |
| Example 22 | Chemical Formula 6 | Chemical Formula 1-2 |
| | (4.0) | (0.1) |
| Example 23 | Chemical Formula 7 | Chemical Formula 1-2 |
| | (2.5) | (0.1) |
| Example 24 | Chemical Formula 7 | Chemical Formula 1-2 |
| | (3.5) | (0.1) |
| Example 25 | Chemical Formula 7 | Chemical Formula 2-3 |
| | (3.5) | (0.1) |
| Example 26 | Chemical Formula 7 | Chemical Formula 1-2 |
| | (4.0) | (0.1) |
| Comparative | Chemical Formula 6 | — |
| Example 1 | (3.0) | |
| Comparative | Chemical Formula 6 | Chemical Formula 9 |
| Example 2 | (3.0) | (0.1) |
| Comparative | Chemical Formula 6 | Chemical Formula 10 |
| Example 3 | (3.0) | (0.1) |
| Comparative | Chemical Formula 7 | — |
| Example 4 | (3.0) | |
| Comparative | Chemical Formula 7 | Chemical Formula 9 |
| Example 5 | (3.0) | (0.1) |
| Comparative | Chemical Formula 7 | Chemical Formula 10 |
| Example 6 | (3.0) | (0.1) |
| Comparative | Chemical Formula 6 | — |
| Example 7 | (2.5) | |
| Comparative | Chemical Formula 6 | — |
| Example 8 | (4.0) | |
| Comparative | Chemical Formula 7 | — |
| Example 9 | (2.5) | |
| Comparative | Chemical Formula 7 | — |
| Example 10 | (4.0) | |

### Evaluation 1: Evaluation of Sensitivity and LER

A linear array of 50 circular pads with a diameter of 500 μm was projected on to the wafer coated with one of the semiconductor photoresist compositions according to the examples and the comparative examples by using EUV light (MET, Lawrence Berkeley National Laboratory Micro Exposure Tool). Herein, pad exposure time was adjusted, so that an EUV dose was increasingly applied to each of the pads.

Subsequently, the photoresist and the substrate were exposed to 160° C. for 120 seconds on a hot plate and then, baked (post-exposure baked (PEB). The baked film was immersed in a developing solution (2-heptanone) for 30 seconds and then, additionally washed with the same developer for 10 seconds to form a negative tone image, i.e., to remove an unexposed portion of the coating. Finally, baking at 150° C. for 2 minutes on the hot plate was performed, completing the process.

The exposed pads were measured with respect to residual photoresist thickness by using an ellipsometer. The residual photoresist thickness for each exposure dose was measured and graphed as a function to the exposure dose to measure Dg (an energy level at which the development was completed) for each type (kind) of photoresists, which is shown in Table 2.

The formed pattern was measured with respect to line edge roughness (LER) by taking a Critical Dimension Scanning Electron Microscope (CD-SEM) image and then, shown in Table 2.

TABLE 2

| | Sensitivity (mJ/cm²) | LER (nm) |
|---|---|---|
| Example 1 | 44 | 1.8 |
| Example 2 | 44 | 1.6 |
| Example 3 | 44 | 1.7 |
| Example 4 | 45 | 2.0 |
| Example 5 | 44 | 1.9 |
| Example 6 | 43 | 1.8 |
| Example 7 | 44 | 1.7 |
| Example 8 | 43 | 1.9 |
| Example 9 | 44 | 1.7 |
| Example 10 | 44 | 1.8 |
| Example 11 | 42 | 1.6 |
| Example 12 | 44 | 1.7 |
| Example 13 | 45 | 2.0 |
| Example 14 | 44 | 1.9 |
| Example 15 | 44 | 1.6 |
| Example 16 | 43 | 1.8 |
| Example 17 | 42 | 1.7 |
| Example 18 | 43 | 1.9 |
| Example 19 | 56 | 1.6 |
| Example 20 | 36 | 1.7 |
| Example 21 | 35 | 1.5 |
| Example 22 | 30 | 2.0 |
| Example 23 | 55 | 1.8 |
| Example 24 | 38 | 1.7 |
| Example 25 | 35 | 1.6 |
| Example 26 | 29 | 1.9 |
| Comparative Example 1 | 54 | 2.5 |
| Comparative Example 2 | 50 | 2.1 |
| Comparative Example 3 | 49 | 2.3 |
| Comparative Example 4 | 50 | 2.6 |
| Comparative Example 5 | 47 | 2.2 |
| Comparative Example 6 | 46 | 2.3 |
| Comparative Example 7 | 62 | 2.3 |
| Comparative Example 8 | 35 | 2.8 |
| Comparative Example 9 | 63 | 2.4 |
| Comparative Example 10 | 37 | 2.9 |

Referring to Table 2, the patterns formed by respectively using the semiconductor photoresist compositions according to Examples 1 to 26 exhibited excellent or suitable sensitivity and small LER, compared to those formed by respectively using the semiconductor photoresist compositions according to Comparative Examples 1 to 10.

Accordingly, the semiconductor photoresist composition according to one or more embodiments was confirmed to exhibit excellent or suitable sensitivity and pattern formality.

### Evaluation 2: Evaluation of Storage Stability

The semiconductor photoresist compositions according to the examples and the comparative example were each stored in a vial under the conditions of room temperature and normal pressure to check whether or not precipitates were observed for 5 days with naked eyes. When the precipitates were observed, X was given, but when the precipitates were not observed, ∘ was given, and the results are shown in Table 3.

TABLE 3

| | Storage stability |
|---|---|
| Example 1 | ◯ |
| Example 2 | ◯ |
| Example 3 | ◯ |
| Example 4 | ◯ |
| Example 5 | ◯ |
| Example 6 | ◯ |
| Example 7 | ◯ |
| Example 8 | ◯ |
| Example 9 | ◯ |
| Example 10 | ◯ |
| Example 11 | ◯ |
| Example 12 | ◯ |
| Example 13 | ◯ |
| Example 14 | ◯ |
| Example 15 | ◯ |
| Example 16 | ◯ |
| Example 17 | ◯ |
| Example 18 | ◯ |
| Comparative Example 1 | X |
| Comparative Example 2 | X |
| Comparative Example 3 | X |
| Comparative Example 4 | X |
| Comparative Example 5 | X |
| Comparative Example 6 | X |

Referring to Table 3, each of the semiconductor photoresist compositions of the examples exhibited no precipitates even after 5 days and no change in viscosity and turbidity. In contrast, the photoresist compositions of the comparative examples all exhibited the precipitates after 5 days and also, changes in viscosity and turbidity. Accordingly, the semiconductor photoresist composition of one or more embodiments was confirmed to exhibit enhanced (e.g., excellent or suitable) storage stability.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. In addition, the term “and/or” or “or” is not to be construed as an exclusive meaning, for example, “A and/or B” or “A or B” is construed to include A, B, A+B, and/or the like. The singular expression includes the plural expression unless the context clearly dictates otherwise. For example, the singular forms “a,” “an,” “one,” and “the” as used herein are intended to include the plural forms as well unless the context clearly indicates differently. Further, the utilization of “may” when describing embodiments of the present disclosure refers to “one or more embodiments of the present disclosure”.

it should be understood that terms such as “comprise(s)/comprising,” “include(s)/including,” and/or “has (have)/having” are intended to designate the presence of an embodied feature, number, step, element, or a combination thereof, but it does not preclude the possibility of the presence or addition of one or more other features, numbers, steps, elements, or a combination thereof. Additionally, the terms “comprise(s)/comprising,” “include(s)/including,” “have/has/having,” or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the context of the present disclosure and unless otherwise defined, the terms “use,” “using,” and “used” may be considered synonymous with the terms “utilize,” “utilizing,” and “utilized,” respectively.

As utilized herein, the term “about,” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, ±20%, ±10%, or ±5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In one or more embodiments, the system for forming patterns may include a coating module, exposure module, bake module, developer module, and etching module, each configured to perform the respective steps (acts) of the method described herein. These modules may be implemented utilizing suitable hardware, software, or firmware, and may operate independently or in combination to execute the pattern formation process.

A pattern forming device, a semiconductor forming device and/or any other relevant devices or components according to embodiments of the present invention described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Hereinbefore, certain embodiments of the present disclosure have been described and illustrated, however, it is apparent to a person with ordinary skill in the art that the present disclosure is not limited to the embodiment as described, and may be variously modified and transformed without departing from the teachings and scope of the present disclosure. Accordingly, the modified or transformed embodiments as such may not be understood separately from the technical ideas and aspects of the present disclosure, and the modified embodiments are within the scope of the claims of the present disclosure. It is further to be understood that the scope of the present disclosure is defined by the appended claims and equivalents thereof rather than the detailed description described above, and all modifications and alterations derived from the claims and their equivalents fall within the scope of the present disclosure.

Reference Numerals

| | |
|---|---|
| 100: substrate | 102: thin film |
| 104: resist underlayer | 106: photoresist film |
| 106a: unexposed region | 106b: exposed region |
| 108: photoresist pattern | 112: organic film pattern |
| 110: patterned mask | 114: thin film pattern |

What is claimed is:

1. A semiconductor photoresist composition, comprising
an organometallic compound;
a compound represented by Chemical Formula 1 or Chemical Formula 2; and
a solvent: 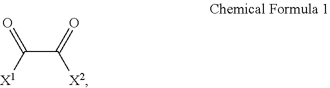
wherein, in Chemical Formula 1,
X¹ and X² are each independently a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, a substituted or unsubstituted C3 to C20 cycloalkyl group, a substituted or unsubstituted C3 to C20 cycloalkenyl group, a substituted or unsubstituted C2 to C20 heterocycloalkyl group, a substituted or unsubstituted C3 to C20 heteroaryl group, or a substituted or unsubstituted C6 to C20 aryl group, and/or X¹ and X² are linked to each other to form a single or a plurality of rings; and 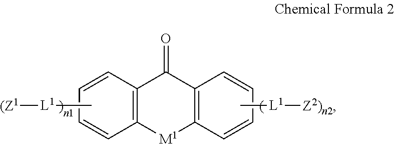
wherein, in Chemical Formula 2,
M¹ is —C(═O)—, —O—, —S—, —N(-L^{x}-R^{x})—, or a combination thereof, L^{x} being a single bond or a substituted or unsubstituted C1 to C5 alkylene group, and R^{x} being hydrogen, a carboxyl group, or a substituted or unsubstituted C1 to C5 alkyl group,
L¹ and L² are each independently a single bond or a substituted or unsubstituted C1 to C5 alkylene group,
Z¹ and Z² are each independently a hydroxyl group, a halogen, a cyano group, a cyano-containing group, an amino group, an ammonium group, an amide group, a nitro group, a carboxyl group, an ester group, a sulfone group, a sulfonate group, a substituted or unsubstituted C1 to C30 alkoxy group, a substituted or unsubstituted C1 to C30 alkyl group, a substituted or unsubstituted C2 to C30 alkenyl group, a substituted or unsubstituted C2 to C30 alkynyl group, or a combination thereof, and
n1 and n2 are each independently one of integers from 0 to 4.

2. The semiconductor photoresist composition as claimed in claim 1, wherein in Chemical Formula 1,
X¹ and X² are each independently a substituted or unsubstituted C1 to C20 alkoxy group, a substituted or unsubstituted C6 to C20 aryl group, or a combination thereof, and
at least one selected from among X¹ and X² is a substituted or unsubstituted C6 to C20 aryl group.

3. The semiconductor photoresist composition as claimed in claim 1, wherein in Chemical Formula 1,
X¹ and X² are each independently a substituted or unsubstituted C1 to C20 alkyl group, a substituted or unsubstituted C3 to C10 cycloalkyl group, a substituted or unsubstituted C6 to C20 aryl group, or a combination thereof, or
X¹ and X² are linked to each other to form a single or a plurality of rings.

4. The semiconductor photoresist composition as claimed in claim 1, wherein in Chemical Formula 2,
Z¹ and Z² are each independently a halogen, a carboxyl group, a sulfonate group, a substituted or unsubstituted C1 to C20 alkoxy group, or a substituted or unsubstituted C1 to C20 alkyl group.

5. The semiconductor photoresist composition as claimed in claim 1, wherein the compound represented by Chemical Formula 1 comprises one or more selected from among compounds of Group 1:

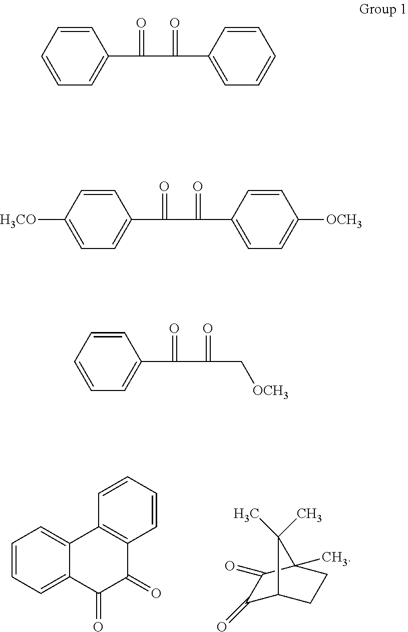 [SMILES: O=C(C(=O)c1ccccc1)c1ccccc1 ; COc1ccc(C(=O)C(=O)c2ccc(OC)cc2)cc1 ; COCC(=O)C(=O)c1ccccc1 ; O=C1C(=O)c2ccccc2-c2ccccc21 ; CC12CCC(C(=O)C1=O)C2(C)C]

6. The semiconductor photoresist composition as claimed in claim 1, wherein the compound represented by Chemical Formula 2 comprises one or more selected from among compounds of Group 2:

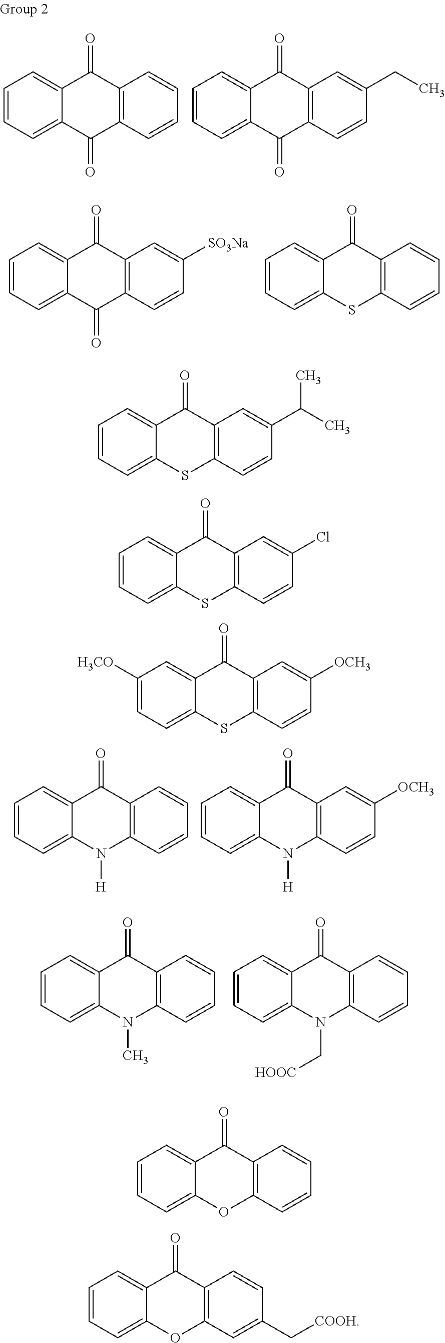

7. The semiconductor photoresist composition as claimed in claim 1, wherein the compound represented by Chemical Formula 1 or Chemical Formula 2 is in an amount of 0.01 wt % to 5 wt % based on a total weight of 100 wt % of the semiconductor photoresist composition.

8. The semiconductor photoresist composition as claimed in claim 1, wherein the organometallic compound is in an amount of 0.5 wt % to 30 wt % based on a total weight of 100 wt % of the semiconductor photoresist composition.

9. The semiconductor photoresist composition as claimed in claim 1, wherein the composition further comprises an additive of a surfactant, a crosslinking agent, a leveling agent, organic acid, a quencher, or a combination thereof.

10. The semiconductor photoresist composition as claimed in claim 1, wherein the organometallic compound is an organotin compound containing at least one of an organic oxy group or an organic carbonyloxy group.

11. The semiconductor photoresist composition as claimed in claim 1, wherein the organometallic compound is represented by Chemical Formula 3: 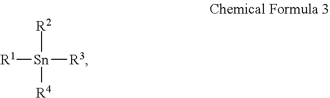
and
wherein, in Chemical Formula 3,
R¹ is selected from among a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, and a substituted or unsubstituted C7 to C30 arylalkyl group,
R² to R⁴ are each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, an alkoxy or aryloxy group (—OR^{b}), an acyloxy or a carboxyl group (—O(CO)R^{c}), an alkylamido or dialkylamido group (—NR^{d}R^{e}), an amidato group (—NR^{f}(COR^{g}), an amidinato group (—NR^{h}C(NRⁱ)R^{j}), an alkylthio or arylthio group (—SR^{k}), or a thiocarboxyl group (—S(CO)R^{l}), R^{b} and R^{k} being each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and R^{c}, R^{d}, R^{e}, R^{f}, R^{g}, R^{h}, Rⁱ, R^{j}, and R^{l} being each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
at least one selected from among R² to R⁴ is selected from among an alkoxy group and an aryloxy group (—OR^{b}), an acyloxy group and a carboxyl group (—O(CO)R^{c}), an alkylamido group and an dialkylamido group (—NR^{d}R^{e}), an amidato group (—NR^{f}(CO)R^{g}), an amidinato group (—NR^{h}C(NRⁱ)R^{j}), an alkylthio group and an arylthio group (—SR^{k}), and thiocarboxyl group (—S(CO)R^{l}), R^{b} and R^{k} being each independently a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and R^{c}, R^{d}, R^{e}, R^{f}, R^{g}, R^{h}, Rⁱ, R^{j}, and R^{l} being each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

12. The semiconductor photoresist composition as claimed in claim 11, wherein at least one selected from among R² to R⁴ is selected from among an alkoxy group and an aryloxy group (—OR^{b}), and an acyloxy group and a carboxyl group (—O(CO)R^{c}), R^{b} being a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and R^{c} being hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

13. The semiconductor photoresist composition as claimed in claim 12, wherein R¹ is selected from among a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, and a substituted or unsubstituted C7 to C20 arylalkyl group,
R^{b} is a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} is hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

14. The semiconductor photoresist composition as claimed in claim 1, wherein the organometallic compound is represented by Chemical Formula 4 or Chemical Formula 5: 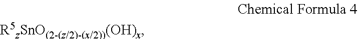
wherein, in Chemical Formula 4,
R⁵ is a C1 to C31 hydrocarbyl group, 0<z≤2, and 0<(z+x)≤4; and 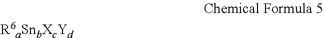
1 wherein, in Chemical Formula 5,
R⁶ is a substituted or unsubstituted C1 to C20 alkyl group, a substituted or unsubstituted C3 to C20 cycloalkyl group, a substituted or unsubstituted C2 to C20 aliphatic unsaturated organic group comprising one or more double bonds or triple bonds, a substituted or unsubstituted C6 to C30 aryl group, a substituted or unsubstituted C4 to C30 heteroaryl group, a carbonyl group, an ethylene oxide group, a propylene oxide group, or a combination thereof,
X is sulfur(S), selenium (Se), or tellurium (Te),
Y is —OR^{m} or —OC(═O)Rⁿ,
R^{m} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof,
Rⁿ is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
a, b, c, and d are each independently an integer of 1 to 20.

15. A method, comprising
forming an etching-objective layer on a substrate;
applying the semiconductor photoresist composition as claimed in claim 1 to the etching-objective layer to form a photoresist film;
patterning the photoresist film to form a photoresist pattern; and
etching the etching-objective layer utilizing the photoresist pattern as an etching mask,
wherein the method is a method of forming patterns.

16. A system, comprising:
means for forming an etching-objective layer on a substrate;
means for coating the semiconductor photoresist composition of claim 1 on the etching-objective layer to form a photoresist film;
means for patterning the photoresist film to form a photoresist pattern; and
means for etching the etching-objective layer utilizing the photoresist pattern as an etching mask,
wherein the system is a system of forming patterns.

17. A system, comprising:
a coating module configured to apply the semiconductor photoresist composition of claim 1 to a substrate bearing an etching-objective layer to form a photoresist film;
an exposure module configured to pattern the photoresist film;
a bake module configured to perform post-apply bake and post-exposure bake;
a developer module configured to develop the patterned photoresist film to form a photoresist pattern; and
an etching module configured to etch the etching-objective layer utilizing the photoresist pattern as an etching mask,
wherein the system is a system of forming patterns.
